(19) United States
(12) Patent Application Publication
(10) Pub. No.: US 2025/0183005 A1
(43) Pub. Date: Jun. 5, 2025

(54) SUBSTRATE PROCESSING METHOD

(71) Applicant: SAMSUNG ELECTRONICS CO., LTD., Suwon-si (KR)

(72) Inventors: Changho Kim, Suwon-si (KR); Songyun Kang, Suwon-si (KR); Kyung-Sun Kim, Suwon-si (KR); Donghyeon Na, Suwon-si (KR); Minyoung Hur, Suwon-si (KR)

(21) Appl. No.: 18/747,191

(22) Filed: Jun. 18, 2024

(30) Foreign Application Priority Data
Dec. 1, 2023 (KR) 10-2023-0172663

(51) Int. Cl. H01J 37/32

(52) U.S. Cl. CPC H01J 37/32174; H01J 37/32091; H01J 2237/334

(57) ABSTRACT

An example substrate processing method comprises placing a substrate into a substrate processing apparatus, supplying the substrate processing apparatus with a process gas, and controlling plasma in the substrate processing apparatus. The step of controlling the plasma includes controlling the plasma in a first mode, controlling the plasma in a second mode after a termination of the first mode, and after a termination of the second mode, controlling the plasma in a third mode. The step of controlling the plasma in the first mode includes applying a first non-sinusoidal voltage to the substrate processing apparatus. A duty of the first non-sinusoidal voltage is changed based on the first mode being advanced.

### CROSS-REFERENCE TO RELATED APPLICATION

This application claims priority under 35 U.S.C § 119 to Korean Patent Application No. 10-2023-0172663 filed on Dec. 1, 2023, in the Korean Intellectual Property Office, the disclosure of which is hereby incorporated by reference in its entirety.

### BACKGROUND

A semiconductor device may be fabricated through various processes. For example, the semiconductor device may be manufactured through a photolithography process, an etching process, a deposition process, and a plating process on a substrate. The plasma may be used in etching and deposition processes on a substrate. A radio-frequency (RF) power may be applied to a substrate processing apparatus to generate and control the plasma. A behavior of the plasma may be changed based on an aspect of RF power.

### SUMMARY

The present disclosure relates to a substrate processing method capable of precisely controlling plasma, a substrate processing method capable of processing a substrate in various ways, and a substrate processing method capable of performing a high-aspect-ratio etching.

The object of the present disclosure is not limited to the mentioned above, and other objects which have not been mentioned above will be clearly understood to those skilled in the art from the following description.

In some implementations, a substrate processing method may comprise: placing a substrate into a substrate processing apparatus; supplying the substrate processing apparatus with a process gas; and controlling plasma in the substrate processing apparatus. The step of controlling the plasma may include: controlling the plasma in a first mode; after a termination of the first mode, controlling the plasma in a second mode; and after a termination of the second mode, controlling the plasma in a third mode. The step of controlling the plasma in the first mode may include applying a first non-sinusoidal voltage to the substrate processing apparatus. A duty of the first non-sinusoidal voltage may be changed while the first mode is advanced.

In some implementations, a substrate processing method may comprise: controlling plasma in a first mode, the plasma being in a substrate processing apparatus; and after the first mode, controlling the plasma in a second mode in the substrate processing apparatus. The step of controlling the plasma in the first mode may include: applying a first source power to the substrate processing apparatus; and applying a first bias voltage to the substrate processing apparatus while the first source power is applied. The step of controlling the plasma in the second mode may include: applying a second source power to the substrate processing apparatus; and applying a second bias voltage to the substrate processing apparatus while the second source power is applied. The step of applying the first bias voltage to the substrate processing apparatus may include: applying a 1-1^{st} non-sinusoidal voltage to the substrate processing apparatus; and after the 1-1^{st} non-sinusoidal voltage is applied, applying a 1-2^{nd} non-sinusoidal voltage to the substrate processing apparatus. A duty of the 1-2^{nd} non-sinusoidal voltage may be different from a duty of the 1-1^{st} non-sinusoidal voltage.

In some implementations, a substrate processing method may comprise: placing a substrate into a substrate processing apparatus; and processing the substrate in the substrate processing apparatus. The step of processing the substrate may include: supplying the substrate processing apparatus with a process gas; simultaneously applying a first source power and a first bias voltage to the substrate processing apparatus; and simultaneously applying a second source power and a second bias voltage to the substrate processing apparatus. A duty of the first bias voltage may be changed when the first source power and the first bias voltage are simultaneously applied to the substrate processing apparatus.

Details of other example implementations are included in the description and drawings.

### BRIEF DESCRIPTION OF THE DRAWINGS

FIG. 1 illustrates a cross-sectional view showing an example of a substrate processing apparatus.

FIG. 2 illustrates an example enlarged cross-sectional view showing section X of FIG. 1.

FIG. 3 illustrates a flow chart showing an example of a substrate processing method.

FIGS. 4, 5, 6, and 7 illustrate example cross-sectional views showing a substrate processing method according to the flow chart of FIG. 3.

FIG. 8 illustrates a graph showing an example of a source power applied in a substrate processing method according to the flow chart of FIG. 3.

FIG. 9 illustrates a graph showing an example of a bias voltage applied in a substrate processing method according to the flow chart of FIG. 3.

FIGS. 10, 11, and 12 illustrate example graphs showing a bias voltage applied in a substrate processing method according to the flow chart of FIG. 3.

FIGS. 13 and 14 illustrate example graphs showing a variation in duty of bias voltage applied in a substrate processing method according to the flow chart of FIG. 3.

### DETAILED DESCRIPTION

The following will now describe some implementations of the present disclosure with reference to the accompanying drawings. Like reference numerals may indicate like components throughout the description.

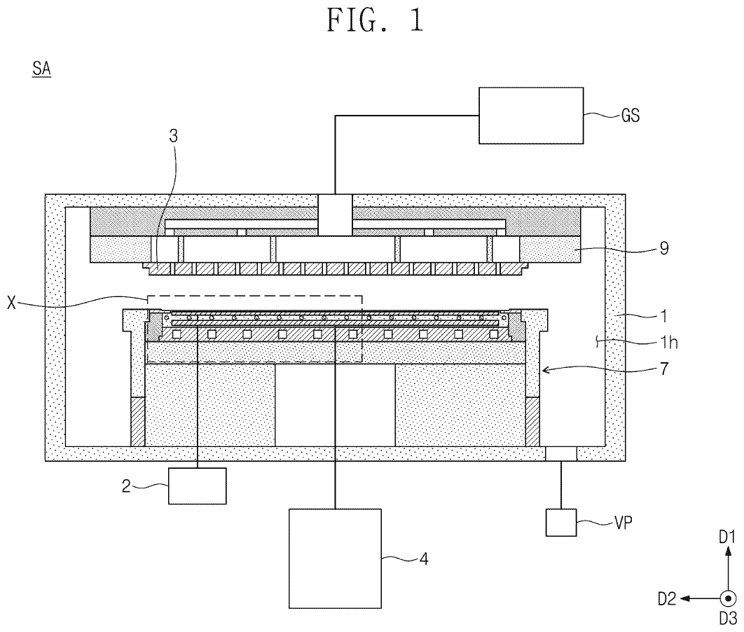

FIG. 1 illustrates a cross-sectional view showing an example of a substrate processing apparatus.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called a vertical direction. In addition, each of the second direction D2 and the third direction D3 may be called a horizontal direction.

Referring to FIG. 1, a substrate processing apparatus SA may be provided. The substrate processing apparatus SA may perform an etching process and/or a deposition process on a substrate. A term “substrate” used in this description may denote a silicon (Si) wafer, but the present disclosure are not limited thereto.

The substrate processing apparatus SA may use plasma to process a substrate. The substrate processing apparatus SA may generate the plasma in various ways. For example, the substrate processing apparatus SA may be a capacitively coupled plasma (CCP) apparatus and/or an inductively coupled plasma (ICP) apparatus. For convenience, the following will illustrate and discuss a CCP type substrate processing apparatus. The substrate processing apparatus SA may include a process chamber 1, a stage 7, a showerhead 3, a direct-current (DC) power generator 2, a plasma power generator 4, a vacuum pump VP, and a gas supply device GS.

The process chamber 1 may provide a process space 1h. A substrate process may be performed in the process space 1h. The process space 1h may be separated from an external space. While a substrate process is performed, the process space 1h may be in a substantial vacuum state. The process chamber 1 may have a cylindrical shape, but the present disclosure are not limited thereto.

The stage 7 may be positioned in the process chamber 1. For example, the stage 7 may be positioned in the process space 1h. The stage 7 may support and/or fix a substrate. A substrate process may be performed in a state where a substrate is placed on the stage 7. The stage 7 will be further discussed in detail below.

The showerhead 3 may be positioned in the process chamber 1. For example, the showerhead 3 may be positioned in the process space 1h. The showerhead 3 may be disposed upwardly spaced apart from the stage 7. For example, a fixing member 9 may rigidly place the showerhead 3 on a certain position in the process space 1h. A gas supplied from the gas supply device GS may be uniformly sprayed through the showerhead 3 into the process space 1h.

The DC power generator 2 may apply a DC power to the stage 7. The DC power applied from the DC power generator 2 may rigidly place a substrate on a certain position on the stage 7.

The plasma power generator 4 may supply the stage 7 with a source power and/or a bias voltage. The plasma power generator 4 may include a source power generator and a bias voltage generator. For example, although FIG. 1 shows one plasma power generator 4, the plasma power generator 4 may be divided into two or more power generators. The source power generator may be a device for applying a sinusoidal wave. The bias voltage generator may be a device for applying a non-sinusoidal wave. The source power and/or the bias voltage applied to the stage 7 may control the plasma in the process space 1h. A detailed description thereof will be further discussed below.

The vacuum pump VP may be connected to the process space 1h. The vacuum pump VP may apply a vacuum pressure to the process space 1h while a substrate process is performed.

The gas supply device GS may supply the process space 1h with gas. The gas supply device GS may include a gas tank, a compressor, and a valve. The plasma may be generated from a portion of gas supplied from the gas supply device GS to the process space 1h.

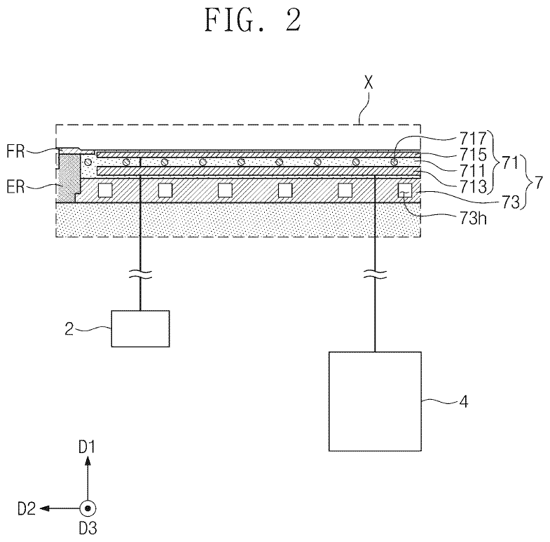

FIG. 2 illustrates an example enlarged cross-sectional view showing section X of FIG. 1.

Referring to FIG. 2, the stage 7 may use an electrostatic force to rigidly place a substrate on a certain position. For example, the stage 7 may include an electrostatic chuck (ESC). The stage 7 may include a chuck 71 and a cooling plate 73.

A substrate may be disposed on the chuck 71. The chuck 71 may fix a substrate on a certain position thereof. The chuck 71 may include a chuck body 711, a plasma electrode 713, a chuck electrode 715, and a heater 717.

The chuck body 711 may have a cylindrical shape. The chuck body 711 may include a ceramic, but the present disclosure are not limited thereto. A substrate may be disposed on a top surface of the chuck body 711. The chuck body 711 may be surrounded by a focus ring FR and/or an edge ring ER.

The plasma electrode 713 may be positioned in the chuck body 711. The plasma electrode 713 may include aluminum (Al). The plasma electrode 713 may have a disk shape, but the present disclosure are not limited thereto. The source power and/or the bias voltage may be applied to the plasma electrode 713. For example, the plasma power generator 4 may apply the source power and/or the bias voltage to the plasma electrode 713. The power and/or the bias voltage applied to the plasma electrode 713 may control the plasma in the process space (see 1h of FIG. 1).

It is illustrated and discussed that each of the source power and the bias voltage is applied to one plasma electrode 713, but the present disclosure are not limited thereto. For example, differently from that shown in FIG. 2, two or more electrodes may be provided to generate and/or control the plasma in the chuck body 711. The source power and the bias voltage may be correspondingly applied to two electrodes.

The chuck electrode 715 may be positioned in the chuck body 711. The chuck electrode 715 may be positioned higher than the plasma electrode 713. A DC power may be applied to the chuck electrode 715. For example, the DC power generator 2 may apply the DC power to the chuck electrode 715. The DC power applied to the chuck electrode 715 may rigidly place a substrate on a certain position on the chuck body 711. The chuck electrode 715 may include aluminum (Al), but the present disclosure are not limited thereto.

The heater 717 may be positioned in the chuck body 711. The heater 717 may be positioned between the chuck electrode 715 and the plasma electrode 713. The heater 717 may include a hot wire. For example, the heater 717 may include a concentrically circular shaped hot wire. The heater 717 may radiate heat to the surrounding environment. Therefore, the chuck body 711 may have an increased temperature.

The cooling plate 73 may be positioned below the chuck 71. For example, the chuck 71 may be positioned on the cooling plate 73. The cooling plate 73 may provide a cooling hole 73h. Cooling water may flow through the cooling hole 73h. The cooling water in the cooling hole 73h may absorb heat from the cooling plate 73.

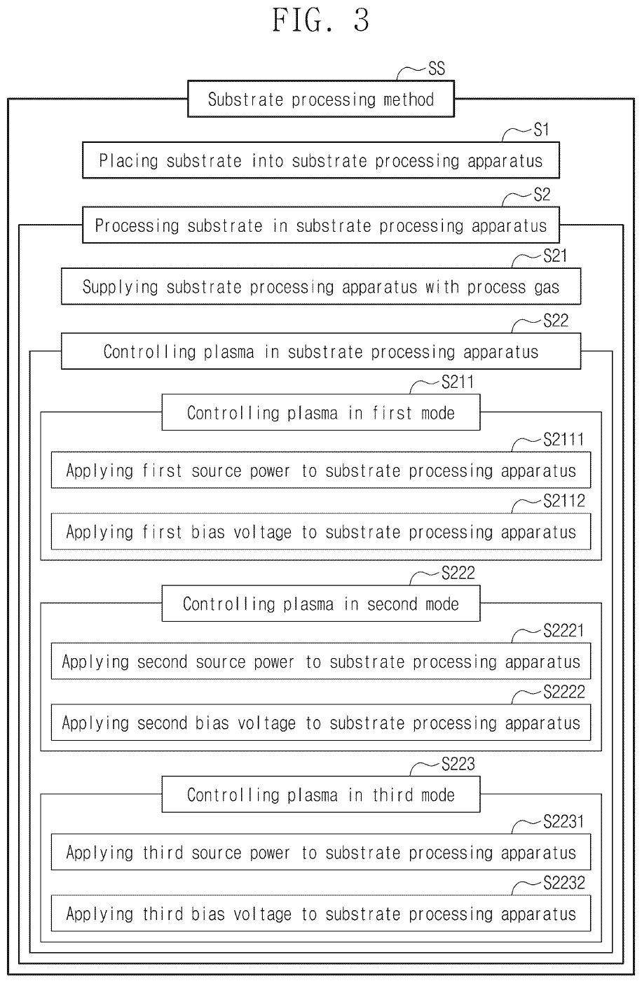

FIG. 3 illustrates a flow chart showing an example of a substrate processing method.

Referring to FIG. 3, a substrate processing method SS may be provided. The substrate processing method SS may be a way of processing a substrate by using the substrate processing apparatus SA discussed with reference to FIGS. 1 and 2. The substrate processing method SS may include placing a substrate into a substrate processing apparatus (S1) and processing the substrate disposed in the substrate processing apparatus (S2).

The substrate process step S2 may include supplying the substrate processing apparatus with a process gas (S21) and controlling plasma in the substrate processing apparatus (S22).

The plasma control step S22 may include controlling the plasma in a first mode (S221), controlling the plasma in a second mode (S222), and controlling the plasma in a third mode (S223).

The first mode control step S221 may include applying a first source power to the substrate processing apparatus (S2211) and applying a first bias voltage to the substrate processing apparatus (S2212).

The second mode control step S222 may include applying a second source power to the substrate processing apparatus (S2221) and applying a second bias voltage to the substrate processing apparatus (S2222). The second mode control step S222 may be performed after a termination of the first mode control step S221.

The third mode control step S223 may include applying a third source power to the substrate processing apparatus (S2231) and applying a third bias voltage to the substrate processing apparatus (S2232). The third mode control step S223 may be performed after a termination of the second mode control step S222.

After the third mode control step S223, the first mode control step S221 may be performed again. For example, the first mode, the second mode, and the third mode may be sequentially alternately repeated.

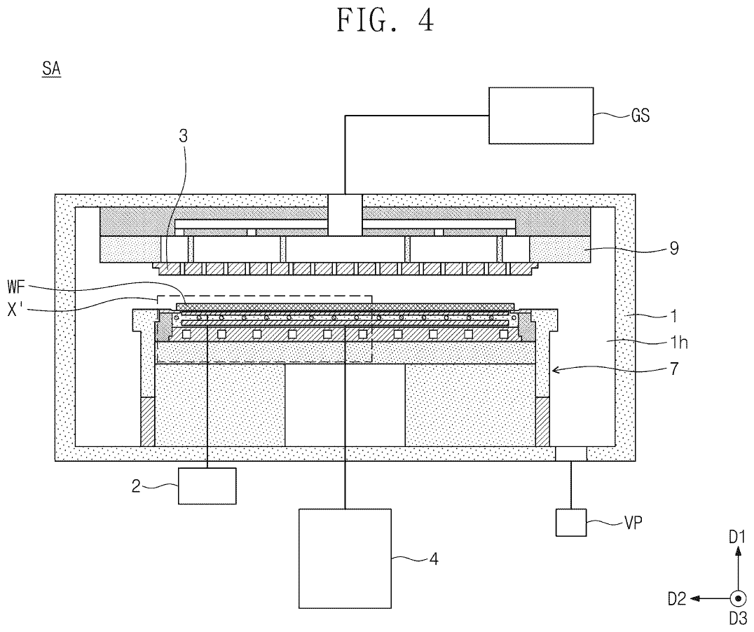

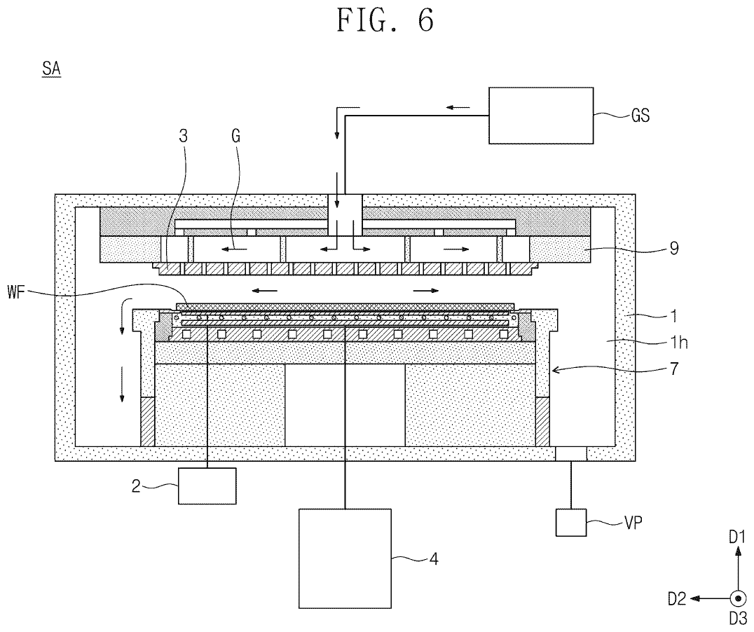

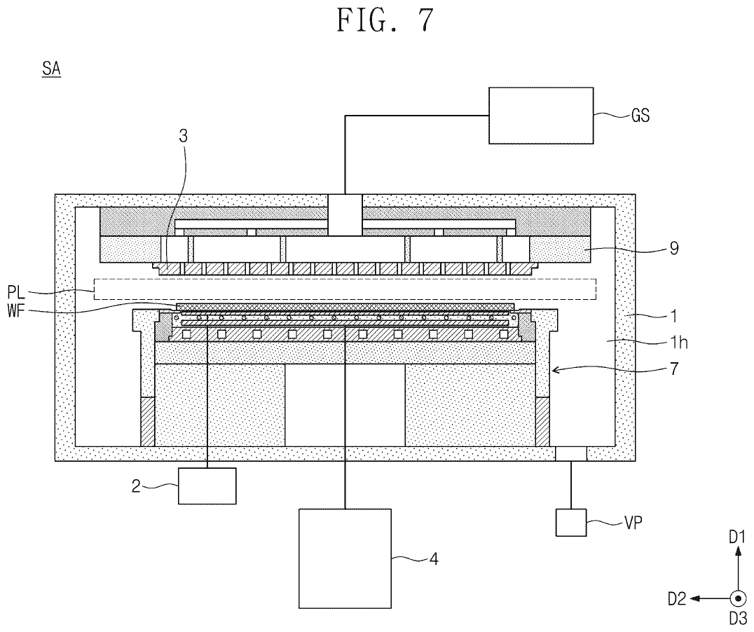

The substrate processing method SS will be discussed in detail below with reference to FIGS. 4 to 14.

FIGS. 4, 5, 6, and 7 illustrate example cross-sectional views showing a substrate processing method according to the flow chart of FIG. 3.

Referring to FIGS. 3, 4, and 5, the substrate placement step S1 may include placing a wafer WF on the stage 7. The stage 7 may fix the substrate WF. For example, the stage 7 may use a chucking power applied from the DC power generator 2 to the chuck electrode 715 to thereby fix the substrate WF on a certain position on the stage 7.

Referring to FIGS. 3, 6, and 7, the gas supply step S21 may include allowing a process gas GS supplied from the gas supply device GS to travel through the showerhead 3 to the substrate WF. A portion of the process gas GS may become plasma PL. For example, the source power may form an electric field in the process space 1h, and the electric field may convert a portion of the process gas GS into the plasma PL. The plasma PL may process the substrate WF. For example, the plasma PL may be controlled to perform an etching process on the substrate WF. A detailed description thereof will be further discussed below.

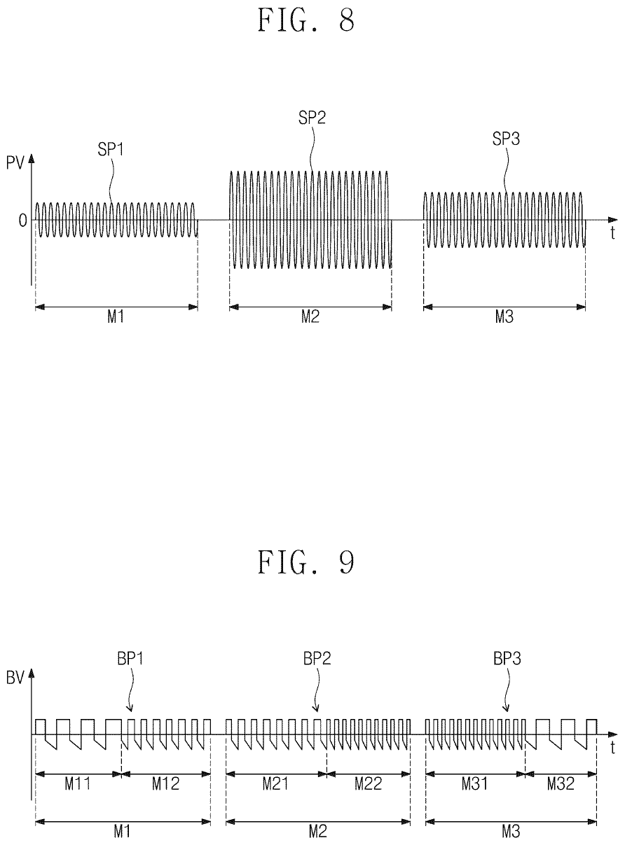

FIG. 8 illustrates a graph showing an example of a source power applied in a substrate processing method according to the flow chart of FIG. 3.

Referring to FIG. 8, a horizontal axis may indicate time. A vertical axis may indicate voltage. A graph of FIG. 8 may mean a source power.

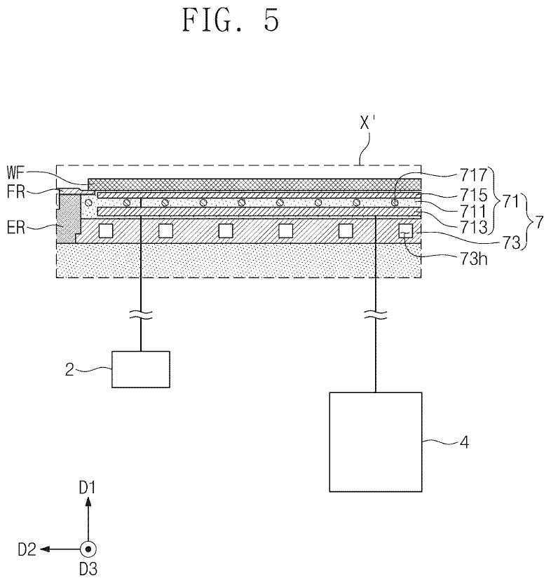

Referring to FIGS. 3, 7, and 8, the first source power step S2211 may include applying a first source power SP1 to the stage 7. For example, the first source power SP1 may be applied from the plasma power generator 4 to the plasma electrode (see 713 of FIG. 5). The first source power SP1 may be, for example, a radio-frequency (RF) power. The first source power SP1 may be constant. For example, the first source power SP1 may not be changed while a first mode M1 is advanced. The first source power SP1 may have a frequency of about 20 MHz to about 80 MHz. For example, the first source power SP1 may have a frequency of about 60 MHz.

The present disclosure, however, are not limited thereto. Although not shown, the first source power SP1 may be supplied in a first macro-pulse type. For example, differently from that shown in FIG. 8, the first source power SP1 may be supplied in a first macro-pulse type in which on/off is repeated.

The second source power step S2221 may include applying a second source power SP2 to the stage 7. For example, the second source power SP2 may be applied from the plasma power generator 4 to the plasma electrode (see 713 of FIG. 5). The second source power SP2 may be, for example, a radio-frequency (RF) power. The second source power SP2 may be applied after the first source power SP1 is applied. The second source power SP2 may be different from the first source power SP1. For example, the second source power SP2 may have a frequency and an amplitude different from those of the first source power SP1. The second source power SP2 may be constant. For example, the second source power SP2 may not be changed while a second mode M2 is advanced. The second source power SP2 may have a frequency of about 20 MHz to about 80 MHz. For example, the second source power SP2 may have a frequency of about 60 MHz.

The present disclosure, however, are not limited thereto. Although not shown, the second source power SP2 may be supplied in a macro-pulse type. For example, differently from that shown in FIG. 8, the second source power SP2 may be supplied in a second macro-pulse type in which on/off is repeated. The second macro-pulse may be substantially the same as or similar to the first macro-pulse, but the present disclosure are not limited thereto.

The third source power step S2231 may include applying a third source power SP3 to the stage 7. For example, the third source power SP3 may be applied from the plasma power generator 4 to the plasma electrode (see 713 of FIG. 5). The third source power SP3 may be, for example, a radio-frequency (RF) power. The third source power SP3 may be applied after the second source power SP2 is applied. The third source power SP3 may be different from each of the first source power SP1 and the second source power SP2. For example, the third source power SP3 may have a frequency and an amplitude different from those of the first source power SP1 and those of the second source power SP2. The third source power SP3 may be constant. For example, the third source power SP3 may not be changed while a third mode M3 is advanced. The third source power SP3 may have a frequency of about 20 MHz to about 80 MHz. For example, the third source power SP3 may have a frequency of about 60 MHz.

The present disclosure, however, are not limited thereto. Although not shown, the third source power SP3 may be supplied in a macro-pulse type. For example, differently from that shown in FIG. 8, the third source power SP3 may be supplied in a third macro-pulse type in which on/off is repeated. The third macro-pulse may be substantially the same as or similar to the first macro-pulse, but the present disclosure are not limited thereto.

It is illustrated and discussed that a source power is applied to the stage 7, but the present disclosure are not limited thereto. For example, a source power may be applied to the showerhead 3. Alternatively, in the case of an inductively coupled plasma (ICP) apparatus, a source power may be applied to a coil that is disposed upwardly from the stage 7.

FIG. 9 illustrates a graph showing an example of a bias voltage applied in a substrate processing method according to the flow chart of FIG. 3.

Referring to FIG. 9, a horizontal axis may indicate time. A vertical axis may indicate voltage. A graph of FIG. 9 may mean a bias voltage.

Referring to FIGS. 3 and 9, the first bias voltage step S2212 may include applying a first bias voltage BP1 to the stage 7. For example, the first bias voltage BP1 may be applied from the plasma power generator 4 to the plasma electrode (see 713 of FIG. 5). The first bias voltage BP1 may be, for example, a non-sinusoidal voltage. The first bias voltage BP1 may be called a first non-sinusoidal voltage. The first bias voltage BP1 may have a frequency of about 200 kHz to about 600 kHz. For example, the first bias voltage BP1 may have a frequency of about 400 kHz.

The first bias voltage step S2212 may be performed substantially simultaneously with the first source power step S2211. Similar to the first source power (see SP1 of FIG. 8), the first bias voltage BP1 may be supplied in a macro-pulse type. A macro-pulse of the first bias voltage BP1 may be substantially the same as or similar to the first macro-pulse of the first source power SP1, but the present disclosure are not limited thereto. The first bias voltage BP1 may not be constant. A duty of the first bias voltage BP1 may be changed while the first mode M1 is advanced. For example, the duty of the first bias voltage BP1 may decrease while the first mode M1 is advanced. As shown in FIG. 9, based on the duty of the first bias voltage BP1, the first mode M1 may be classified into a 1-1^{st} mode M11 and a 1-2^{nd} mode M12. A detailed description thereof will be further discussed below.

The second bias voltage step S2222 may include applying a second bias voltage BP2 to the stage 7. For example, the second bias voltage BP2 may be applied from the plasma power generator 4 to the plasma electrode (see 713 of FIG. 5). The second bias voltage BP2 may be, for example, a non-sinusoidal voltage. The second bias voltage BP2 may be called a second non-sinusoidal voltage. The second bias voltage BP2 may have a frequency of about 200 kHz to about 600 kHz. For example, the second bias voltage BP2 may have a frequency of about 400 kHz.

The second bias voltage step S2222 may be performed substantially simultaneously with the second source power step S2221. Similar to the second source power (see SP2 of FIG. 8), the second bias voltage BP2 may be supplied in a macro-pulse type. A macro-pulse of the second bias voltage BP2 may be substantially the same as or similar to the second macro-pulse of the second source power SP2, but the present disclosure are not limited thereto. The second bias voltage BP2 may not be constant. A duty of the second bias voltage BP2 may be changed while the second mode M2 is advanced. For example, the duty of the second bias voltage BP2 may decrease while the second mode M2 is advanced. As shown in FIG. 9, based on the duty of the second bias voltage BP2, the second mode M2 may be classified into a 2-1^{st} mode M21 and a 2-2^{nd} mode M22. A detailed description thereof will be further discussed below.

The third bias voltage step S2232 may include applying a third bias voltage BP3 to the stage 7. For example, the third bias voltage BP3 may be applied from the plasma power generator 4 to the plasma electrode (see 713 of FIG. 5). The third bias voltage BP3 may be, for example, a non-sinusoidal voltage. The third bias voltage BP3 may be called a third non-sinusoidal voltage. The third bias voltage BP3 may have a frequency of about 200 kHz to about 600 kHz. For example, the third bias voltage BP3 may have a frequency of about 400 kHz.

The third bias voltage step S2232 may be performed substantially simultaneously with the third source power step S2231. Similar to the third source power (see SP3 of FIG. 8), the third bias voltage BP3 may be supplied in a macro-pulse type. A macro-pulse of the third bias voltage BP3 may be substantially the same as or similar to the third macro-pulse of the third source power SP3, but the present disclosure are not limited thereto. The third bias voltage BP3 may not be constant. A duty of the third bias voltage BP3 may be changed while the third mode M3 is advanced. For example, the duty of the third bias voltage BP3 may increase while the third mode M3 is advanced. As shown in FIG. 9, based on the duty of the third bias voltage BP3, the third mode M3 may be classified into a 3-1^{st} mode M31 and a 3-2^{nd} mode M32. A detailed description thereof will be further discussed below.

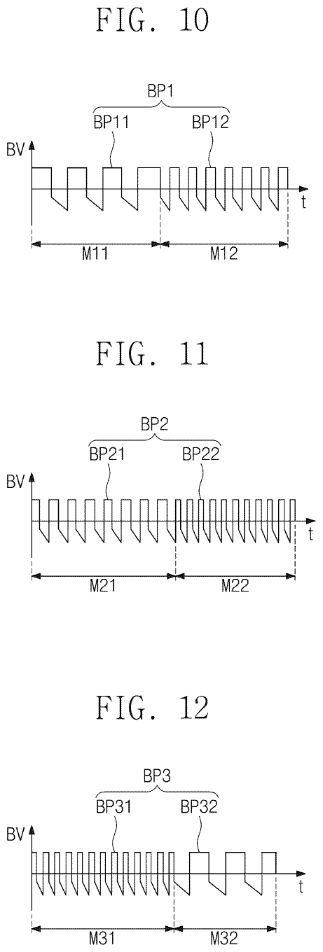

FIGS. 10, 11, and 12 illustrate example graphs showing a bias voltage applied in a substrate processing method according to the flow chart of FIG. 3.

Referring to FIG. 10, a horizontal axis may indicate time. A vertical axis may indicate voltage. A graph of FIG. 10 may mean the first bias voltage BP1. The first bias voltage BP1 may include a 1-1^{st} bias voltage BP11 and a 1-2^{nd} bias voltage BP12. The 1-1^{st} mode M11 may refer to a mode in which the 1-1^{st} bias voltage BP11 is applied. The 1-2^{nd} mode M12 may refer to a mode in which the 1-2^{nd} bias voltage BP12 is applied. A duty of the 1-1^{st} bias voltage BP11 may be different from that of the 1-2^{nd} bias voltage BP12. The duty of the 1-2^{nd} bias voltage B12 may be less than that of the 1-1^{st} bias voltage BP11. In the first mode (see M1 of FIG. 9), there may be a reduction in the duty of the first bias voltage BP1. For example, the duty of the first bias voltage BP1 may linearly decrease. A detailed description thereof will be further discussed below.

Referring to FIG. 11, a horizontal axis may indicate time. A vertical axis may indicate voltage. A graph of FIG. 11 may mean the second bias voltage BP2. The second bias voltage BP2 may include a 2-1^{st} bias voltage BP12 and a 2-2^{nd} bias voltage BP22. The 2-1^{st} mode M21 may refer to a mode in which the 2-1^{st} bias voltage BP21 is applied. The 2-2^{nd} mode M22 may refer to a mode in which the 2-2^{nd} bias voltage BP22 is applied. A duty of the 2-1^{st} bias voltage BP21 may be, for example, substantially the same as or similar to that of the 1-2^{nd} bias voltage (see BP12 of FIG. 10). The duty of the 2-1^{st} bias voltage BP21 may be different from that of the 2-2^{nd} bias voltage BP22. The duty of the 2-2^{nd} bias voltage B22 may be less than that of the 2-1^{st} bias voltage BP21. In the second mode (see M2 of FIG. 9), there may be a reduction in the duty of the second bias voltage BP2. For example, the duty of the second bias voltage BP2 may linearly decrease. A detailed description thereof will be further discussed below.

Referring to FIG. 12, a horizontal axis may indicate time. A vertical axis may indicate voltage. A graph of FIG. 12 may mean the third bias voltage BP3. The third bias voltage BP3 may include a 3-1^{st} bias voltage BP31 and a 3-2^{nd} bias voltage BP32. The 3-1^{st} mode M31 may refer to a mode in which the 3-1^{st} bias voltage BP31 is applied. The 3-2^{nd} mode M32 may refer to a mode in which the 3-2^{nd} bias voltage BP32 is applied. A duty of the 3-1^{st} bias voltage BP31 may be, for example, substantially the same as or similar to that of the 2-2^{nd} bias voltage (see BP22 of FIG. 11). The duty of the 3-1^{st} bias voltage BP31 may be different from that of the 3-2^{nd} bias voltage BP32. The duty of the 3-2^{nd} bias voltage B32 may be greater than that of the 3-1^{st} bias voltage BP31. In the third mode (see M3 of FIG. 9), there may be an increase in the duty of the third bias voltage BP3. A duty of the 3-2^{nd} bias voltage BP32 may be, for example, substantially the same as or similar to that of the 1-1^{st} bias voltage (see BP11 of FIG. 10). For example, the duty of the third bias voltage BP3 may linearly increase. A detailed description thereof will be further discussed below.

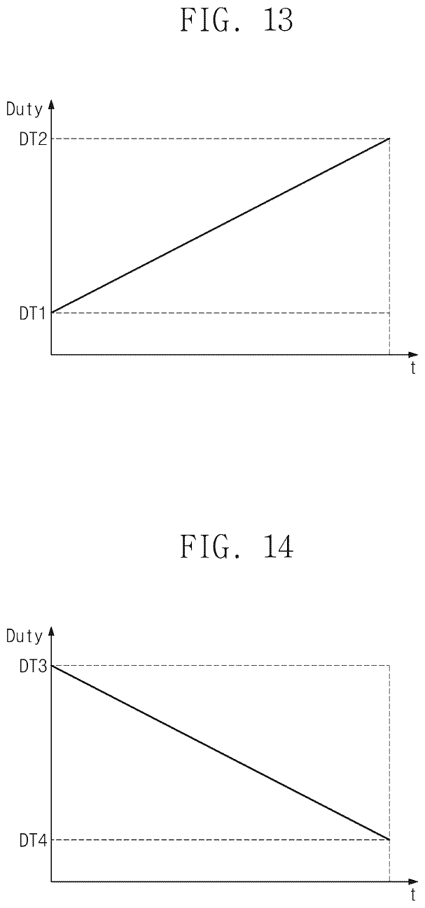

FIGS. 13 and 14 illustrate example graphs showing a variation in duty of bias voltage applied in a substrate processing method according to the flow chart of FIG. 3.

Referring to FIG. 13, a horizontal axis may indicate time. A vertical axis may indicate a duty of bias voltage. When there is an increase in the duty of bias voltage in one mode, the duty of bias voltage may linearly increase with time. For example, as shown in FIG. 13, the duty of bias voltage may increase from a first duty DT1 to a second duty DT2. The first duty DT1 may be about 10% to about 30%. For example, the first duty DT1 may be about 20%. The second duty DT2 may be about 60% to about 80%. For example, the second duty DT2 may be about 70%. The present disclosure, however, are not limited thereto.

Referring to FIG. 14, a horizontal axis may indicate time. A vertical axis may indicate a duty of bias voltage. When there is a reduction in the duty of bias voltage in one mode, the duty of bias voltage may linearly decrease with time. For example, as shown in FIG. 14, the duty of bias voltage may decrease from a third duty DT3 to a fourth duty DT4. The third duty DT3 may be substantially the same as or similar to the second duty (see DT2 of FIG. 13). The fourth duty DT4 may be substantially the same as or similar to the first duty (see DT1 of FIG. 13).

It is illustrated and discussed that a duty of bias voltage is linearly changed in one mode, but the present disclosure are not limited thereto. For example, in one mode, a duty of bias voltage may be changed in other ways.

According to a substrate processing method in accordance with some implementations of the present disclosure, a duty of bias voltage may be changed in one mode. Therefore, plasma may be precisely controlled to process a substrate in various ways. For example, plasma may be accurately controlled to perform a high-aspect-ratio etching process on a substrate.

According to a substrate processing method of the present disclosure, plasma may be precisely controlled.

According to a substrate processing method of the present disclosure, a substrate may be processed in various ways.

According to a substrate processing method of the present disclosure, a high-aspect-ratio etching may be available.

Effects of the present disclosure are not limited to the mentioned above, other effects which have not been mentioned above will be clearly understood to those skilled in the art from the following description.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure has been described in connection with some implementations of the present disclosure illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A substrate processing method, comprising:
placing a substrate into a substrate processing apparatus;
supplying the substrate processing apparatus with a process gas; and
controlling plasma in the substrate processing apparatus,
wherein controlling the plasma includes:
controlling the plasma in a first mode;
after a termination of the first mode, controlling the plasma in a second mode; and
after a termination of the second mode, controlling the plasma in a third mode,
wherein controlling the plasma in the first mode includes applying a first non-sinusoidal voltage to the substrate processing apparatus, and
wherein a duty of the first non-sinusoidal voltage is configured to change based on the first mode being advanced.

2. The substrate processing method of claim 1, wherein the duty of the first non-sinusoidal voltage increases based on the first mode being advanced.

3. The substrate processing method of claim 2, wherein the duty of the first non-sinusoidal voltage linearly increases based on the first mode being advanced.

4. The substrate processing method of claim 1, wherein the duty of the first non-sinusoidal voltage decreases based on the first mode being advanced.

5. The substrate processing method of claim 1, wherein controlling the plasma in the first mode includes applying a first source power to the substrate processing apparatus based on the first non-sinusoidal voltage being applied.

6. The substrate processing method of claim 5, wherein the first source power is unchanged based on the first mode being advanced.

7. The substrate processing method of claim 5, wherein the first source power and the first non-sinusoidal voltage are applied to a stage of the substrate processing apparatus.

8. The substrate processing method of claim 1, wherein
controlling the plasma in the second mode includes applying a second non-sinusoidal voltage to the substrate processing apparatus, and
controlling the plasma in the third mode includes applying a third non-sinusoidal voltage to the substrate processing apparatus,
wherein a duty of the second non-sinusoidal voltage is configured to change based on the second mode being advanced, and
wherein a duty of the third non-sinusoidal voltage is configured to change based on the third mode being advanced.

9. The substrate processing method of claim 8, wherein
controlling the plasma in the second mode includes applying a second source power to the substrate processing apparatus based on the second non-sinusoidal voltage being applied, and
controlling the plasma in the third mode includes applying a third source power to the substrate processing apparatus based on the third non-sinusoidal voltage being applied,
wherein the second source power is unchanged based on the second mode being advanced, and
wherein the third source power is unchanged based on the third mode being advanced.

10. The substrate processing method of claim 9, wherein
the duty of the first non-sinusoidal voltage is changed from a first duty to a second duty based on the first mode being advanced,
the duty of the second non-sinusoidal voltage is changed from the second duty to a third duty based on the second mode being advanced, and
the duty of the third non-sinusoidal voltage is changed from the third duty to the first duty based on the third mode being advanced.

11. The substrate processing method of claim 1, wherein controlling the plasma includes sequentially and repeatedly performing the first mode, the second mode, and the third mode.

12. A substrate processing method, comprising:
controlling plasma in a first mode, the plasma being in a substrate processing apparatus; and
after the first mode, controlling the plasma in a second mode in the substrate processing apparatus,
wherein controlling the plasma in the first mode includes:
applying a first source power to the substrate processing apparatus; and
applying a first bias voltage to the substrate processing apparatus based on the first source power being applied,
wherein controlling the plasma in the second mode includes:
applying a second source power to the substrate processing apparatus; and
applying a second bias voltage to the substrate processing apparatus based on the second source power being applied,
wherein applying the first bias voltage to the substrate processing apparatus includes:
applying a 1-1^{st} non-sinusoidal voltage to the substrate processing apparatus; and
after the 1-1^{st} non-sinusoidal voltage is applied, applying a 1-2^{nd} non-sinusoidal voltage to the substrate processing apparatus,
wherein a duty of the 1-2^{nd} non-sinusoidal voltage is different from a duty of the 1-1^{st} non-sinusoidal voltage.

13. The substrate processing method of claim 12, wherein the duty of the 1-2^{nd} non-sinusoidal voltage is greater than the duty of the 1-1^{st} non-sinusoidal voltage.

14. The substrate processing method of claim 13, wherein
the duty of the 1-1^{st} non-sinusoidal voltage is 10% to 30%, and
the duty of the 1-2^{nd} non-sinusoidal voltage is 60% to 80%.

15. The substrate processing method of claim 12, wherein
the first source power is unchanged based on the first mode being advanced, and
the second source power is unchanged based on the second mode being advanced.

16. The substrate processing method of claim 12, comprising: after the second mode, controlling the plasma in a third mode in the substrate processing apparatus,
wherein controlling the plasma in the third mode includes:
applying a third source power to the substrate processing apparatus; and
applying a third bias voltage to the substrate processing apparatus based on the third source power being applied.

17. A substrate processing method, comprising:
placing a substrate into a substrate processing apparatus; and
processing the substrate in the substrate processing apparatus,
wherein processing the substrate includes:
supplying the substrate processing apparatus with a process gas;
simultaneously applying a first source power and a first bias voltage to the substrate processing apparatus; and
simultaneously applying a second source power and a second bias voltage to the substrate processing apparatus,
wherein a duty of the first bias voltage is configured to change based on the first source power and the first bias voltage being simultaneously applied to the substrate processing apparatus.

18. The substrate processing method of claim 17, wherein the duty of the first bias voltage is linearly changed based on the first source power and the first bias voltage being simultaneously applied to the substrate processing apparatus.

19. The substrate processing method of claim 17, wherein the first source power is unchanged based on the first source power and the first bias voltage being simultaneously applied to the substrate processing apparatus.

20. The substrate processing method of claim 17, wherein a duty of the second bias voltage is constant based on the second source power and the second bias voltage being simultaneously applied to the substrate processing apparatus.
